(19) United States
(12) Patent Application Publication
(10) Pub. No.: US 2008/0014770 A1
(43) Pub. Date: Jan. 17, 2008

(54) Coupling assembly

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314, US

(73) Assignee: TAI-SOL ELECTRONICS CO., LTD., TAIPEI CITY (TW)

(21) Appl. No.: 11/606,098

(22) Filed: Nov. 30, 2006

(30) Foreign Application Priority Data
Jul. 12, 2006 (TW) 95212244

(51) Int. Cl. H05K 1/00

(52) U.S. Cl. 439/79

(57) ABSTRACT

A coupling assembly includes a first board and a second board. The first board includes a plurality of first conductive pieces located at an end surface thereof and spaced from one another in a predetermined interval. The second board includes a plurality of second conductive pieces spaced from one another in a predetermined interval and located at at least one end surface thereof close to a lateral edge thereof. The second board includes a plurality of recessed portions recessed inward from the lateral edge thereof and located among the second conductive pieces. The first and second boards are perpendicular to each other. The conductive pieces of at least one of the two boards are provided with soldering. The soldering of each of the conductive pieces is heated to liquate out and then contact the perpendicular corresponding conductive pieces to couple the corresponding first and second conductive pieces with each other.

### BACKGROUND OF THE INVENTION

1. Field of the Invention

The present invention relates generally to the art of conductive coupling of boards, and more particularly, to a coupling assembly of two boards.

2. Description of the Related Art

As disclosed in U.S. Pat. No. 6,568,957 entitled “COUPLING ASSEMBLY”, a plurality of conductive pins 14 are mounted on an adaptor circuit board 16 and then the conductive pins are soldered on an external board by surface mounting technology (SMT).

As indicated in the above-mentioned prior art, the adaptor circuit board 16 must be connected with the external board through the conductive pins 14 and they must be conductively coupled through soldering. Because the conductive pins 14 have to be mounted between the adaptor circuit board 16 and the external circuit board, there is relatively one extra set of components. In addition, the intervals among the conductive pins 14 each are too small to be easily positioned, thus being subject to inaccuracy. In light of this, the conductive pins 14 have to be positioned by specific auxiliary jigs or connections.

As indicated above, the conventional coupling assembly not only has more components to cause higher cost but also has to enable the conductive pins to be connected to the adaptor circuit and then soldered on the external circuit to cause double processes.

### SUMMARY OF THE INVENTION

The primary objective of the present invention is to provide a coupling assembly, which is structurally simpler than the prior art and has less components than the prior art without the conductive pieces.

The secondary objective of the present invention is to provide a coupling assembly, which can be manufactured more quickly.

The foregoing objectives of the present invention are attained by the coupling assembly composed of two boards defined as a first board and a second board. The first board includes a plurality of first conductive pieces located at an end surface thereof and spaced from one another in a predetermined interval. The second board includes a plurality of second conductive pieces spaced from one another in a predetermined interval and located at at least one end surface thereof close to a lateral edge thereof. The second board includes a plurality of recessed portions recessed inward from the lateral edge thereof and located among the second conductive pieces. The second board contacts against the first board by the lateral edge thereof having the second conductive pieces and the second conductive pieces correspond to the first conductive pieces respectively. The first and second boards are perpendicular to each other. The conductive pieces of at least one of the two boards are provided with soldering. The soldering of each of the conductive pieces is heated to liquate out and then contact the perpendicular corresponding conductive pieces to couple the first conductive pieces with the corresponding second conductive pieces. In light of this, the present invention has rapid, convenient, and low-cost conductive coupling effect.

### BRIEF DESCRIPTION OF THE DRAWINGS

FIG. 1 is a perspective view of a preferred embodiment of the present invention.

FIG. 2 is an enlarged view of a part of the preferred embodiment of the present invention.

FIG. 3 is an exploded view of the preferred embodiment of the present invention.

FIG. 4 is a top view of the preferred embodiment of the present invention.

FIG. 5 is a cross-sectional view taken along a line 5-5 indicated in FIG. 4.

FIG. 6 is an enlarged view of a part of FIG. 5.

FIG. 7 is a cross-sectional view of the preferred embodiment of the present invention, illustrating that the soldering liquates out to complete the connection.

FIG. 8 is another cross-sectional view of the preferred embodiment of the present invention, illustrating that the soldering is disposed on the second board.

FIG. 9 is another cross-sectional view of the preferred embodiment of the present invention, illustrating that the soldering is disposed on the first and second boards.

FIG. 10 is another cross-sectional view of the preferred embodiment of the present invention, illustrating that the second conductive pieces are mounted at two end surfaces of the second board.

### DETAILED DESCRIPTION OF PREFERRED EMBODIMENTS

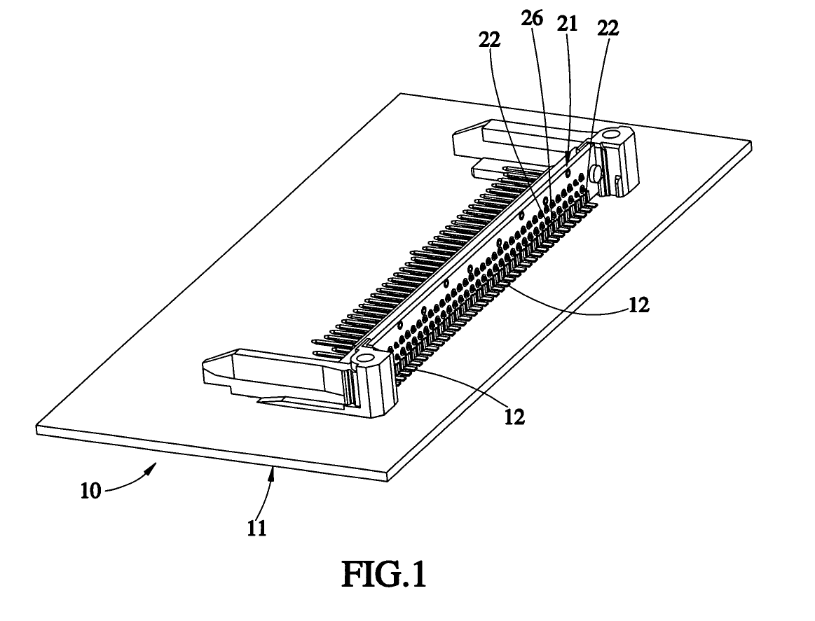

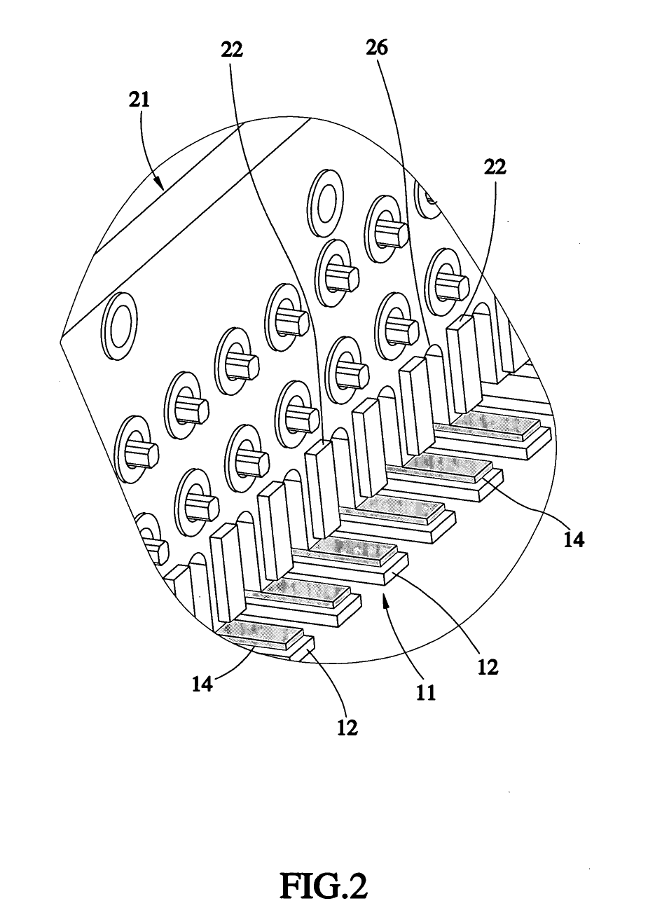

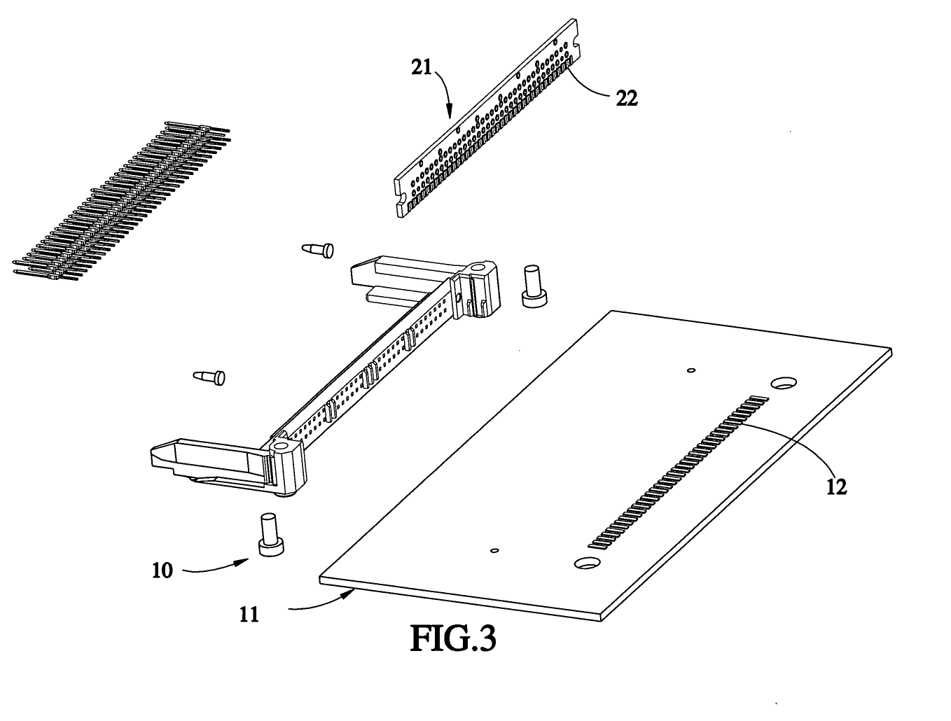

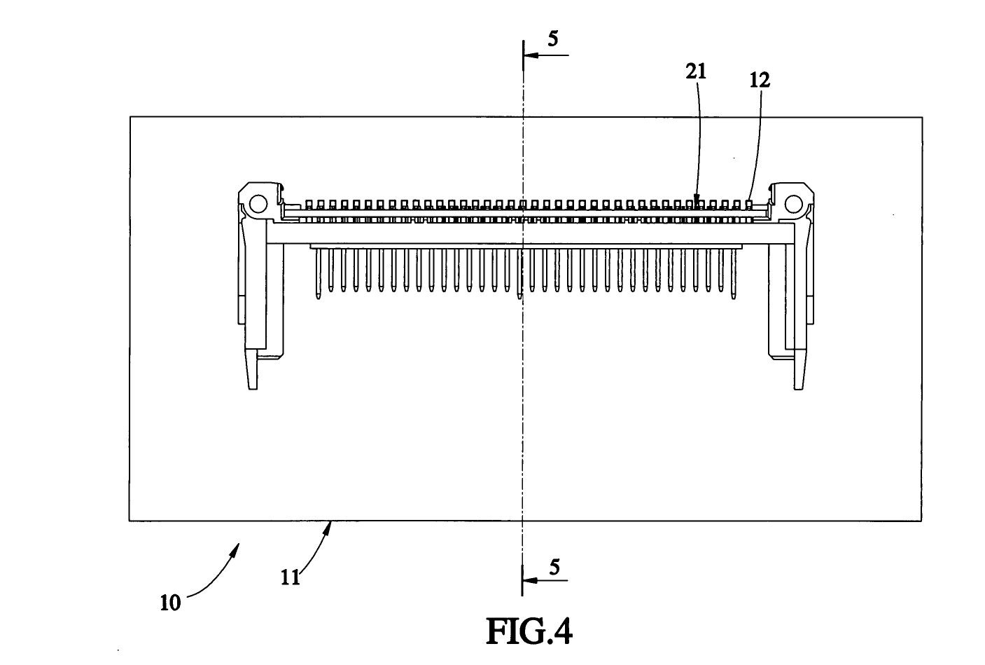

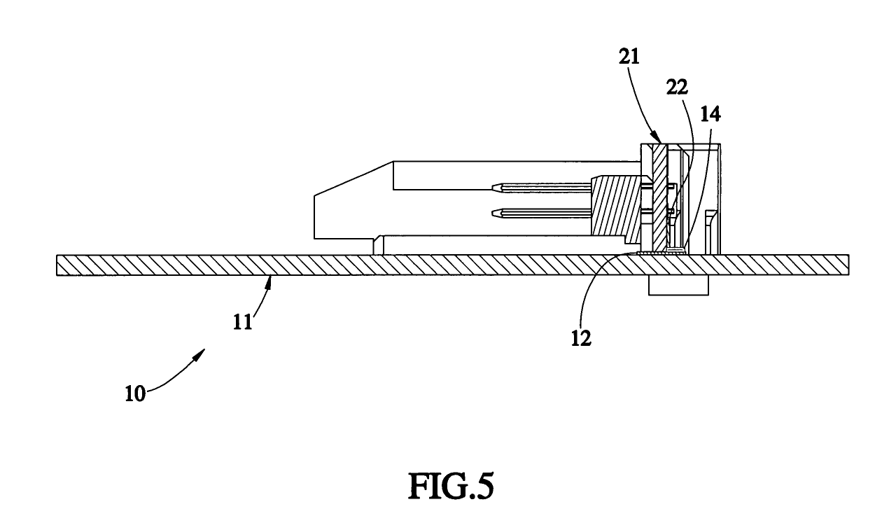

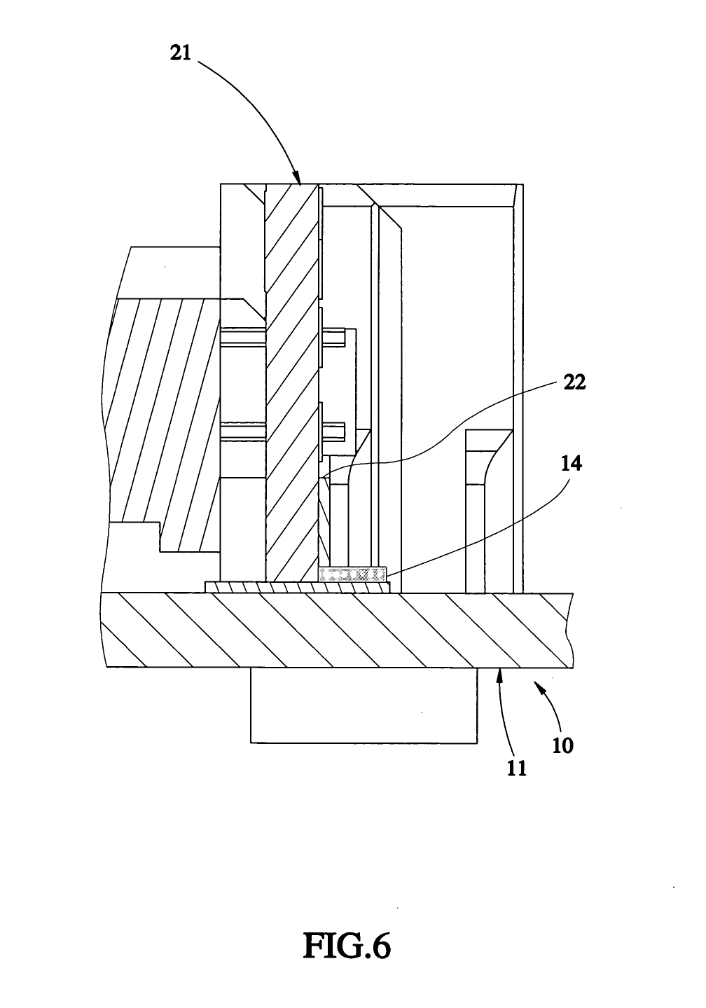

Referring to FIGS. 1-6, a coupling assembly 10 constructed according to a preferred embodiment composed of two boards defined as a first board 11 and a second board 21 respectively.

The first board 11 includes a plurality of first conductive pieces 12 mounted at an end surface and spaced from one another in a predetermined interval. The second board 21 includes a plurality of second conductive pieces 22 spaced from one another in a predetermined interval and mounted at at least end surface thereof abutting a lateral edge thereof. The second board 21 includes a plurality of recessed portions 26 each mounted between each two of the second conductive pieces 22 and recessed inward from the lateral edge thereof.

The second board 21 contacts against the first board 11 by the lateral edge thereof, on which the second conductive pieces 22 are mounted, to enable the second conductive pieces 22 to correspond to the first conductive pieces 12 respectively. The two boards 11 and 21 are substantially perpendicular to each other.

The first conductive pieces 12 of the first board 11 each are disposed with soldering 14 which is shaped like a flat plate.

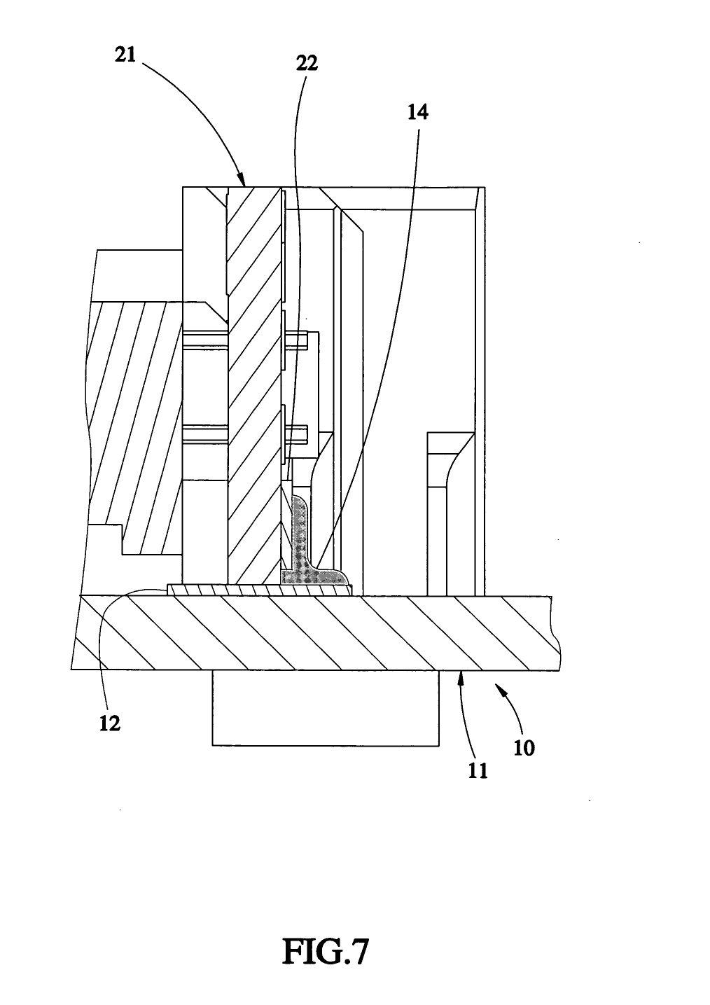

The soldering 14 of the first conductive pieces 12 is heated to liquate out and then contact the second conductive pieces 22. In the meantime, the second conductive pieces 22 is perpendicular to the first conductive pieces 12 to enable the first conductive pieces 12 to be coupled with the corresponding second conductive pieces 22. The status that the soldering 14 liquates out is as shown in FIG. 7.

When the soldering 14 of the first conductive pieces 12 is heated to liquate out, a part of the liquid soldering 14 sticks between the first and second boards 11 and 21 by the capillary action. The recessed portions 26 can stop the capillary action to prevent the liquid soldering 14 of the first conductive pieces 12 from flowing to one another, thus avoiding occurrence of short circuit or defective products.

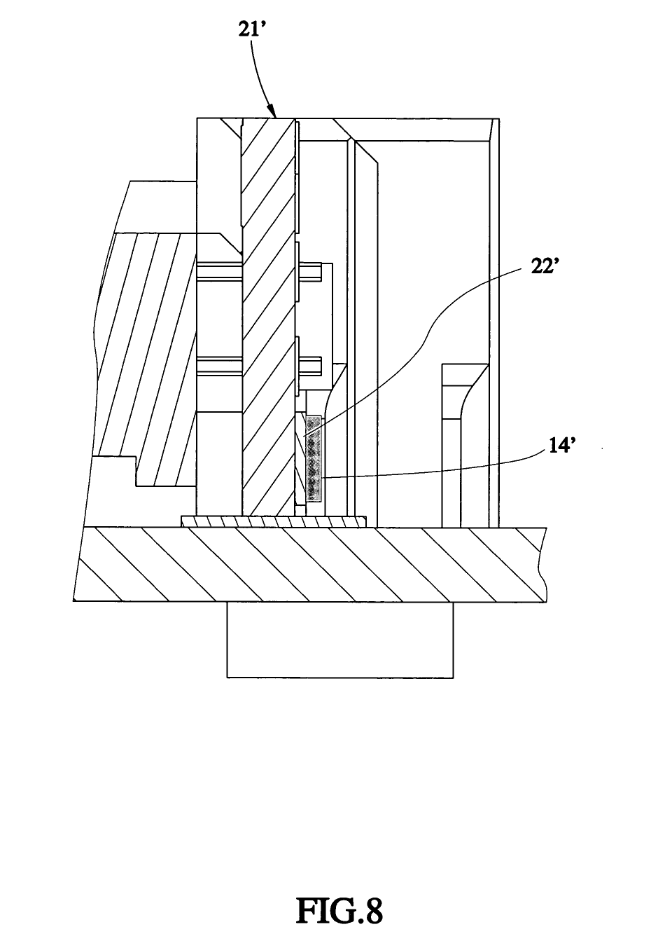

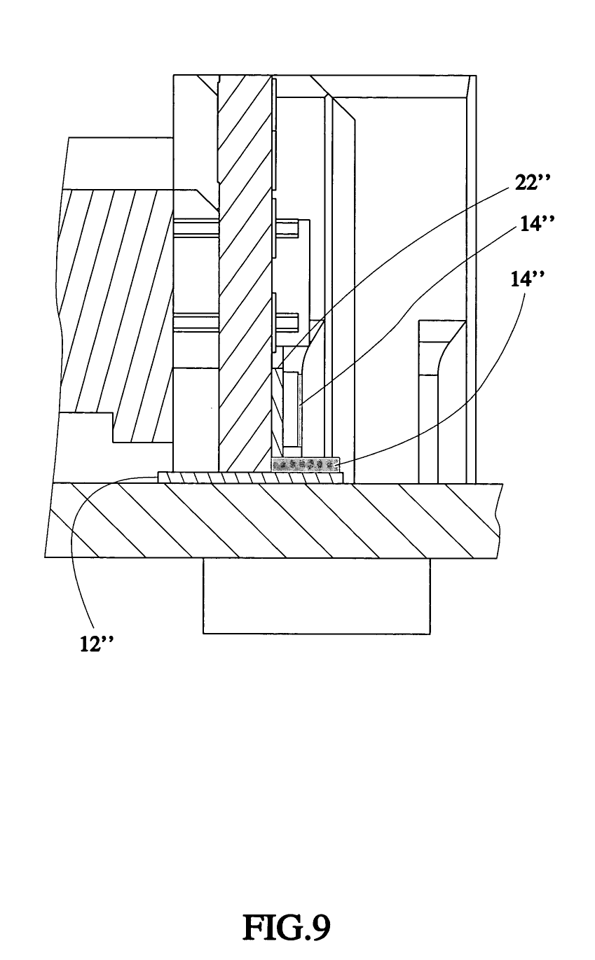

It is to be noted that where the soldering 14 is mounted is not limited to the first conductive pieces 12 and can be alternatively, as shown in FIG. 8, the second conductive pieces 22′ of the second board 21′. As shown in FIG. 9, where the soldering 14 is mounted can alternatively be the first and second conductive pieces 12” and 22″ and then the soldering 14 can likewise contact and couple the corresponding first and second conductive pieces 12″ and 22″ with each other after heated to liquate out.

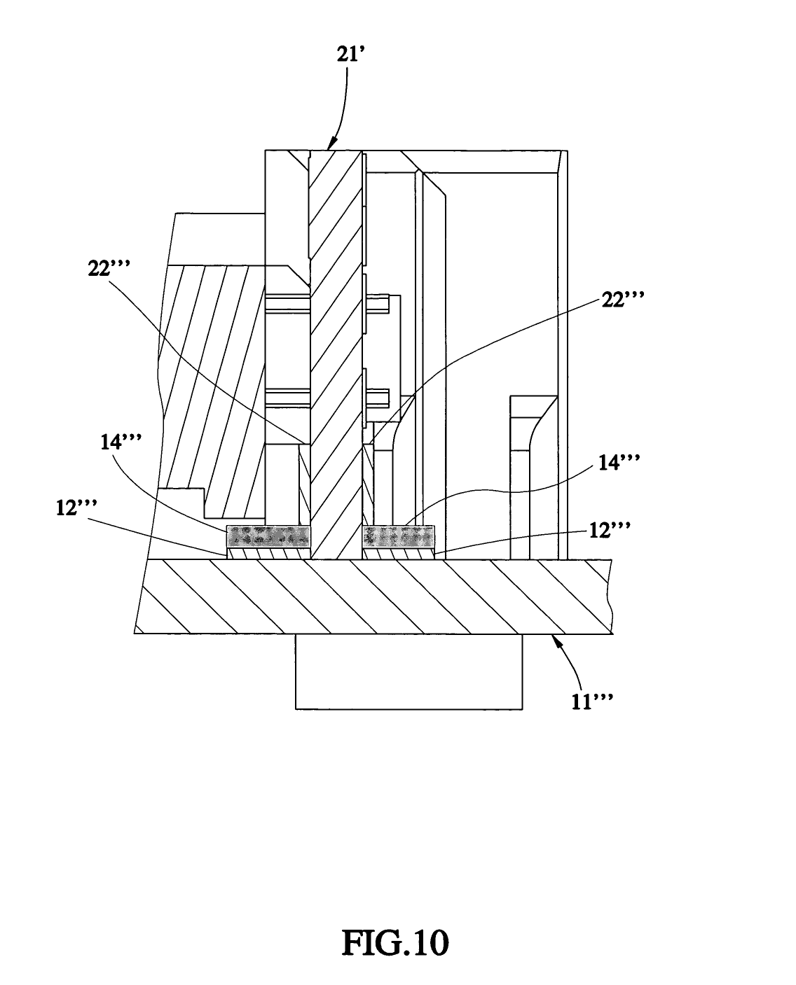

In addition, referring to FIG. 10, the second conductive pieces 22′″ can alternatively be mounted at two opposite end surfaces of the second board 21′″ and two rows of the first conductive pieces 12′″ are mounted on the first board 11′″. When the second board 21′″ is perpendicular to the first board 11′″, the second conductive pieces 22′″ of the two opposite end surfaces of the second board 21′″ correspond to the two rows of the first conductive pieces 12′″ respectively. The soldering 14′″ can be alternatively mounted on the first conductive pieces 12′″.

In conclusion, the present invention includes the following advantages.
1. The present invention directly couples the conductive pieces of the two boards with one another though the soldering without indirect connection of additional conductive pins, such that the components of the present invention are less than those of the prior art to cause lower production cost.
2. Since the conductive pins are excluded in the present invention, the time and the process of soldering the conductive pins can be saved and the production can be time-saving and rapid because of no other processes like jigs and calibration.

Although the present invention has been described with respect to a specific preferred embodiment thereof, it is no way limited to the details of the illustrated structures but changes and modifications may be made within the scope of the appended claims.

What is claimed is:

1. A coupling assembly comprising two boards defined as a first board and a second board, said first board having a plurality of first conductive pieces mounted at an end surface thereof and spaced from one another in a predetermined interval, said second board having a plurality of second conductive pieces spaced from one another and mounted at at least one end surface thereof abutting a lateral edge thereof, said second board having a plurality of recessed portions each mounted between each two of said conductive pieces and recessed inward from the lateral edge thereof;
whereby said second board contacts against said first board by the lateral edge having said second conductive pieces and enables said second conductive pieces to correspond to said first conductive pieces respectively;
wherein said conductive pieces of at least one of said two boards are disposed with soldering, said soldering is heated to liquate out and then contacts the corresponding conductive pieces perpendicular to those of said at least one of said two boards to couple said first conductive pieces with said corresponding second conductive pieces.

2. The coupling assembly as defined in claim 1, wherein said first conductive pieces are disposed with the soldering thereon.

3. The coupling assembly as defined in claim 1, wherein the soldering of each of said conductive pieces is shaped like a flat plate.

4. The coupling assembly as defined in claim 1, wherein said two boards are perpendicular to each other.
